(19) United States
(12) Patent Application Publication
(10) Pub. No.: US 2025/0232200 A1
(43) Pub. Date: Jul. 17, 2025

(54) SUPERCONDUCTING QUANTUM COMPUTER WITH AIR-BRIDGE TYPE SUPERCONDUCTING COUPLER

(71) Applicant: Samsung Electronics Co., Ltd., Suwon-si (KR)

(72) Inventors: Hyeok Shin KWON, Suwon-si (KR); Dae Yun KIM, Suwon-si (KR); Jae Hyeong LEE, Suwon-si (KR); Dae Seok HAN, Suwon-si (KR)

(73) Assignee: Samsung Electronics Co., Ltd., Suwon-si (KR)

(21) Appl. No.: 18/741,379

(22) Filed: Jun. 12, 2024

(30) Foreign Application Priority Data
Jan. 17, 2024 (KR) 10-2024-0007653

(51) Int. Cl. G06N 10/40; H10N 60/01; H10N 60/80

(52) U.S. Cl. CPC G06N 10/40; H10N 60/01; H10N 60/80

(57) ABSTRACT

An air-bridge type superconducting coupler is provided. A frequency-fixed superconducting coupler includes: a bridge over a substrate, the bridge comprised of superconducting material, the bridge having two ends that each comprise a respective contact pad, each contact pad having an electrical connection to a respectively corresponding superconducting qubit, and each contact pad directly or indirectly contacting the substrate, wherein there is a gap between the substrate and a corresponding portion of the bridge that is between the contact pads.

### CROSS-REFERENCE TO RELATED APPLICATIONS

This application claims priority from Korean Patent Application No. 10-2024-0007653, filed on Jan. 17, 2024, in the Korean Intellectual Property Office, the entire disclosure of which is incorporated herein by reference for all purposes.

### BACKGROUND

### 1. Field

The following description relates to an air-bridge type superconducting coupler and a superconducting computing apparatus including the same.

### 2. Description of Related Art

A quantum computer operates based on principles of quantum mechanics, such as quantum superposition and quantum entanglement. A unit element capable of storing information by using principles of quantum mechanics or the information itself is called quantum bit or qubit, which can be used as a basic unit of information and computation in quantum computing.

With growing interest in quantum computers, research has been conducted on various types of qubits. The qubits may be implemented as various types of qubits, such as photonic qubits, ion trap qubits, topological qubits, superconducting qubits, etc., among which the most popular qubits so far are superconducting qubits using superconducting materials.

### SUMMARY

In one general aspect, a superconducting computing apparatus includes: a substrate; superconducting qubits formed on the substrate; a superconducting coupler comprised of a superconducting line and two contact pads disposed at the respective ends of the superconducting line, the contact pads having respective electrical connections with the respective superconducting qubits, wherein the superconducting line is formed as a bridge over the substrate.

The superconducting coupler may be an LC resonance circuit-type coupler.

The superconducting coupler may be a frequency-fixed coupler having a resonant frequency between 1 GHz and 10 GHz.

The superconducting line and the two contact pads may all have three layers including, in order from bottom to top, a superconducting material layer, an insulator layer, and a superconducting material layer.

The superconducting material may include Aluminum (AI), Niobium (Nb), Indium (In), Alpha-Tantalum (α-Ta), Titanium (Ti), Lead (Pb), Vanadium (V), or a compound thereof.

The insulator may have a thickness between 10 nm and 50 nm.

The insulator may include aluminum oxide.

A superconducting material layer at a bottom of a first contact pad may be connected to a capacitor of the superconducting qubit, and a superconducting material layer at a top of a second contact pad may be electrically connected to a capacitor of the superconducting qubit.

The superconducting line and the second contact pad may have a single layer of a superconducting material, and the first contact pad may have three layers including, in order from bottom to top, a superconducting material layer, an insulator layer, and a superconducting material layer.

The bridge may be vertically spaced apart from the substrate by a distance between 5 μm and 50 μm and a space between the bottom of the bridge and the top of the substrate is not occupied by solid material.

The superconducting computing apparatus may include a parasitic capacitor.

The superconducting line may have a length between 100 μm and 1 mm.

The contact pads may each have a length shorter than the length of the superconducting line.

The contact pads may each have an area of 0.05 mm2 or less.

The superconducting line may be formed in a crenelated shape as viewed from above.

The superconducting line may have a total length between 100 μm and 1 mm.

In another general aspect, a frequency-fixed superconducting coupler includes: a bridge over a substrate, the bridge comprised of superconducting material, the bridge having two ends that each comprise a respective contact pad, each contact pad having an electrical connection to a respectively corresponding superconducting qubit, and each contact pad directly or indirectly contacting the substrate, wherein there is a gap between the substrate and a corresponding portion of the bridge that is between the contact pads.

The gap may have a distance, vertically, from the portion of the bridge to the substrate, of 5 μm to 50 μm.

In another general aspect, a method of manufacturing a frequency-fixed superconducting coupler includes: depositing a photoresist on a substrate; then depositing a first layer made of a superconducting material; then depositing a second layer made of an insulator; then depositing a third layer made of a superconducting material; and then removing the photoresist by an etching process to form a bridge over the substrate.

The bridge may be 5 μm to 50 μm above the substrate.

### BRIEF DESCRIPTION OF THE DRAWINGS

FIG. 1 illustrates a structure of a superconducting computing apparatus, according to one or more embodiments.

FIG. 2 illustrates a superconducting computing apparatus including a superconducting coupler, according to one or more embodiments.

FIG. 3A is a cross-sectional view of a superconducting coupler, according to one or more embodiments.

FIG. 3B is a cross-sectional view of a superconducting coupler, according to one or more embodiments.

FIGS. 4A to 4C illustrate a superconducting computing apparatus including a superconducting coupler, according to one or more embodiments.

FIG. 5 illustrates an example in which a superconducting coupler connects distant qubits, according to one or more embodiments.

FIGS. 6A to 6E illustrate steps of manufacturing a frequency-fixed superconducting coupler, according to one or more embodiments.

Throughout the drawings and the detailed description, unless otherwise described or provided, the same or like drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

In the following description, when an element is referred to as being “above” or “below” another element, it may be directly above or below the other element while being in contact with the other element, but it may also be above or below the element without contact with the other element.

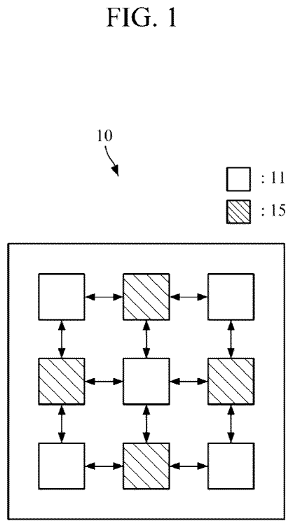

FIG. 1 illustrates a structure of a superconducting qubit-based quantum computing apparatus (hereinafter referred to as a “superconducting computing apparatus”), according to one or more embodiments.

Referring to FIG. 1, a superconducting computing apparatus 10 includes a qubits 11 and qubit couplers 15 connecting the qubits. The qubit couplers 15 are used for quantum entanglement induced by qubit-qubit interactions, etc., and two or more qubits 11 are included in the superconducting computing apparatus 10 such that the qubit couplers 15 are integral to qubit-qubit interactions.

The qubits 11 may be of two types: fixed qubits with a resonant frequency fixed at a specific value, and tunable qubits with a tunable resonant frequency. The qubit couplers 15 may also be of two types: fixed qubit couplers with a resonant frequency fixed at a specific value, and tunable qubit couplers with a tunable resonant frequency.

Unlike a tunable qubit coupler, a fixed qubit coupler need not include a Josephson junction, and may connect qubits through an LC resonator, for example.

Generally, in fabrication of two-dimensional (2D) multi-qubit chips, qubits (or several circuit components including the qubits) may be capacitively or inductively connected on the same plane using a nearest-neighbor connection architecture, and one qubit may be connected up to 4 other qubits. However, with a nearest neighbor connection configuration, some qubit connections may be difficult or impossible. For example, it may be difficult to connect qubits located at various positions, or it may be difficult to connect qubits with circuit components, such that gate driving is restricted, which can limit which quantum computing algorithms can be used.

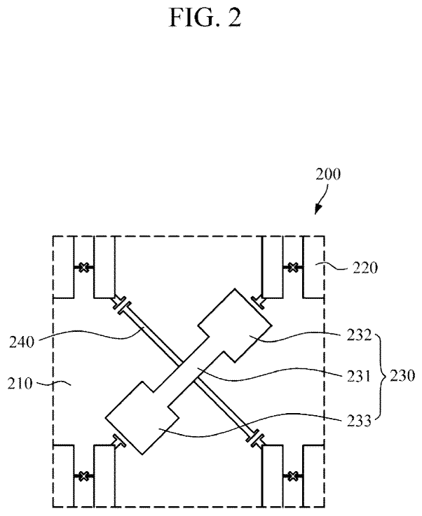

FIG. 2 illustrates an example superconducting computing apparatus including a superconducting coupler, according to As used herein, “superconducting” refers to material capable of superconductivity under various conditions, and the term does not imply that the material is presently or actively superconductive. For example, a superconducting coupler may only become superconductive at a certain temperature, nonetheless, the superconducting coupler is properly deemed “superconducting” even when not at that certain superconductivity-inducing temperature.

A superconducting computing apparatus 200 may include a planar substrate 210, superconducting qubits 220 formed on the substrate, and a superconducting coupler 230 connecting the superconducting qubits 220.

The superconducting coupler 230 may be an LC resonance circuit-type coupler composed of a superconducting material (and possibly other material), and may be a frequency-fixed coupler having a resonance frequency between 1 GHz and 10 GHz.

The superconducting coupler 230 may include a superconducting line 231, and two contact pads 232 and 233 disposed at both ends of the superconducting line 231 and respectively forming electromagnetic connections/couplings with the superconducting qubits 220, in which the superconducting line 231 may be formed as an air bridge (spaced apart from the substrate); the air bridge configuration may accommodate other components, such as a flux line 240 passing underneath the superconducting coupler 230.

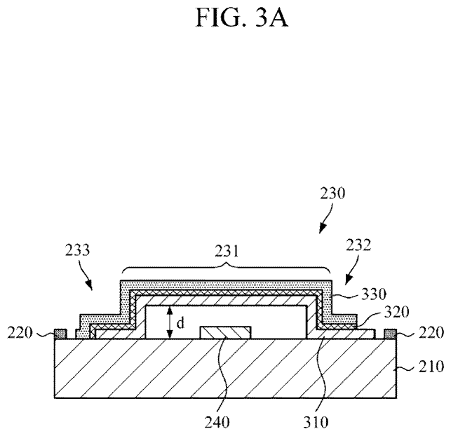

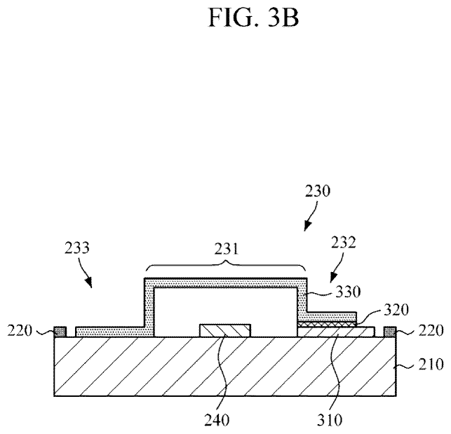

FIG. 3A is a cross-sectional view of a superconducting coupler, according to one or more embodiments. The view is of a cross-section taken along a centerline (as viewed from above) of the superconducting coupler 230.

Referring to FIG. 3A, the superconducting line 231, the first contact pad 232, and the second contact pad 233, which are included in the superconducting coupler 230, may have three layers. The three layers may include a superconducting material layer 310, an insulator layer 320, and a superconducting material layer 330 in order from bottom to top.

The superconducting material may include at least one of Aluminum (AI), Niobium (Nb), Indium (In), Alpha-Tantalum (α-Ta), Titanium (Ti), Lead (Pb), Vanadium (V), or a compound thereof.

The insulator layer 320 may have a thickness between 10 nm and 50 nm, and may include, for example, aluminum oxide (AIOx) with high permittivity and low loss. However, the types of insulator are not limited thereto.

Capacitance may be provided by implementing a capacitor (e.g., parallel-plated capacitor) in the form of the three layers 310, 320, and 330 of the superconducting coupler 230, and inductance may be obtained by implementing an inductor via the superconducting line 231.

That is, by varying the structure (e.g., the area and/or thickness of three layers or the length or thickness of the superconducting line 231, etc.) of the superconducting coupler 230 according to predetermined criteria, a desired LC value required for qubit coupling may be obtained, and a desired resonant frequency may be obtained.

Referring to FIG. 2, as the superconducting line 231, the first contact pad 232, and the second contact pad 233 are formed in a relatively short and thick shape, a level of difficulty in manufacturing may be reduced, and a capacitance may be adjusted by adjusting the thickness of an insulator, where the adjusting is done according to inductance, which has a relatively small value due to the short length, thereby finally implementing the superconducting coupler 230 to have a desired frequency.

The superconducting line 231 may have a length between 100 μm and 1 mm (the length not including the contact pads). The first contact pad 232 and the second contact pad 233 may have a length that is relatively shorter than the length of the superconducting line 231, and the first contact pad 232 and the second contact pad 233 may each have an area of 0.05 mm2 or less, for example. However, the length and area of the superconducting line 231, the first contact pad 232, and the second contact pad 233 are not limited thereto.

Referring to FIG. 3A, to implement the capacitor (the superconducting coupler 230) in a circuit, the superconducting material layer 310 at the bottom of the first contact pad 232 may be electrically connected/coupled to a capacitor of the superconducting qubit 220, and the superconducting material layer 330 at the top of the second contact pad 233 may be electrically connected/coupled to a capacitor of the superconducting qubit 220 (there may be a gap between the contact pads and the qubits).

The superconducting line 231 may be formed as an air bridge with a space formed thereunder, i.e., without the superconducting line 231 contacting the substrate 210. The first contact pad 232 and the second contact pad 233 are supported by (e.g., attached to) the substrate 210 and thus support the air bridge structure.

For example, the superconducting line 231 may be formed as an air bridge which is spaced apart from the substrate 210 by a predetermined distance d, so that another flux line 240 or other circuit components, and the like may be disposed therebetween or pass therethrough. In this case, the predetermined distance d may be a distance between 5 μm and 50 μm from the substrate 210 in a vertical direction (a normal of the plane of the substrate 210), but is not limited thereto.

The superconducting computing apparatus 200 may further include a parasitic capacitor. The predetermined distance d, a dimension of the air bridge structure between the superconducting line 231 and the substrate 210 may be, for example, 5 μm or more. With this feature, a parasitic capacitance may be formed between a structure on the substrate and a pattern on the surface. Although the parasitic capacitance may be relatively small, to reduce the effect of the parasitic capacitance, the superconducting computing apparatus 200 may further include a separate parasitic capacitor.

FIG. 3B is a cross-sectional view of a superconducting coupler, according to one or more embodiments. The cross-section may be along the length of the superconducting coupler 230.

Referring to FIG. 3B, the superconducting line 231 and the second contact pad 233 of the superconducting coupler 230 may have a single layer 330 of a superconducting material, and the first contact pad 232 may have three layers including the superconducting material layer 310, the insulator layer 320, and the superconducting material layer 330 in order from bottom to top. In this case, in order to implement a capacitor in a circuit, the superconducting material layer 310 at the bottom of the first contact pad 232 may be electrically connected to a capacitor of the superconducting qubit 220, and the superconducting material layer 330 (which is formed as a single layer of the second contact pad 233) may be electrically connected to a capacitor of the superconducting qubit 220.

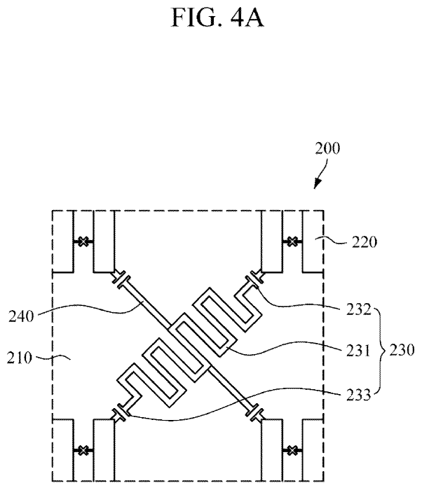

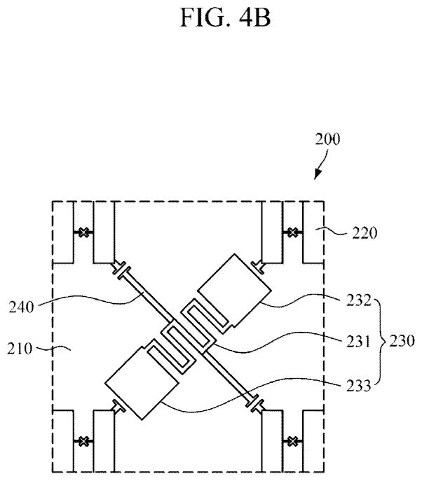

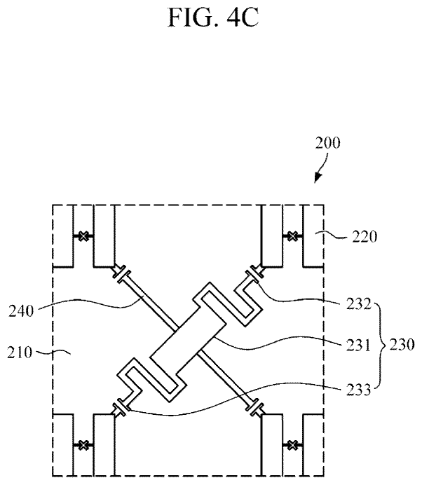

FIGS. 4A to 4C illustrate a superconducting computing apparatus including a superconducting coupler, according to one or more embodiments.

Referring to FIG. 4A, the superconducting coupler 230 may include the superconducting line 231 formed in a meandering or serpentine shape (or specifically, a castle or crenelated shape as viewed from above), and the first contact pad 232 and the second contact pad 233 having a relatively small area. The superconducting line 231 may be formed as an air bridge with a total length between 100 μm and 1 mm, such that the superconducting line 231 may be connected to the superconducting qubit 220 located at a distant position (the total length of the air bridge refers to the distance between its endpoints, not the linear/path length of the material of the air bridge). The entire superconducting coupler 230 may have three layers including a superconducting material layer, an insulator layer, and a superconducting material layer, or only the first contact pad and/or the second contact pad may have three layers.

Referring to FIG. 4B, the superconducting coupler 230 may include the superconducting line 231 with an air bridge formed in a meandering/crenelated/castle shape, and the first contact pad 232 and the second contact pad 233 having a relatively large area.

As illustrated in FIGS. 4A and 4B, an LC value required for qubit coupling may be obtained by varying parameters of the meandering/castle structure, the length of the superconducting line 231, and/or the width or thickness of the two contact pads 232 and 233.

Referring to FIG. 4C, the superconducting coupler 230 may include the superconducting line 231 with an air bridge formed by both a meandering/castle sections and a straight line section therebetween. The first contact pad 232 and the second contact pad 233 may have a relatively small area.

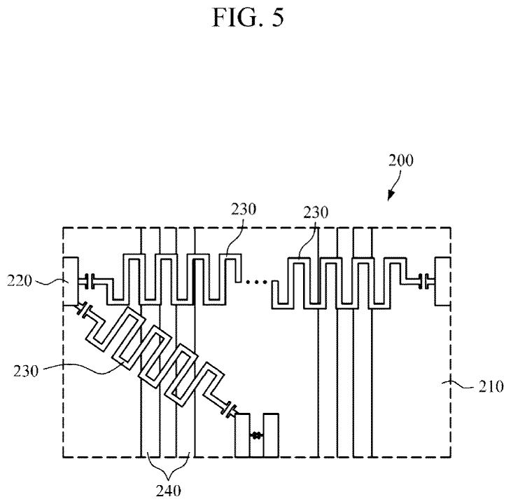

FIG. 5 illustrates an example in which a superconducting coupler connects distant qubits, according to one or more embodiments.

Referring to FIG. 5, the superconducting computing apparatus 200 may connect distant qubits by using a meandering/castle/crenelated structure of an air bridge of the superconducting coupler 230.

Generally, in the nearest neighbor connection method previously used for fabricating two-dimensional (2D) multi-qubit chips, space for connecting qubits is limited, which presents corresponding limitations when implementing various quantum computing algorithms. Using various air-bridge type superconducting couplers, a space under the air bridge may be secured for additional use. This may allow for efficient arrangement of circuit components, in particular, qubits located at distant positions may be connected, thereby increasing connectivity between qubits. As a result, efficient and high-performance multi-qubit chips may be fabricated and more types of quantum computing algorithms become possible to implement.

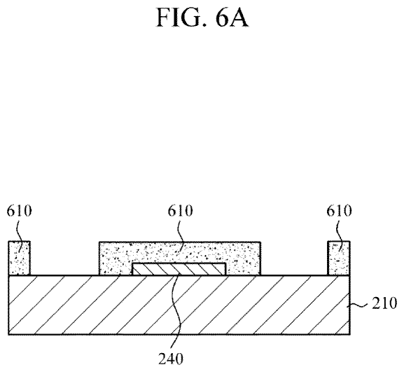

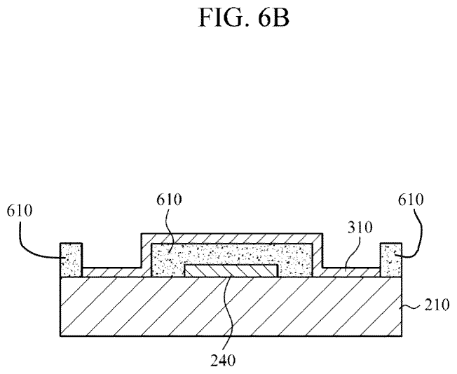

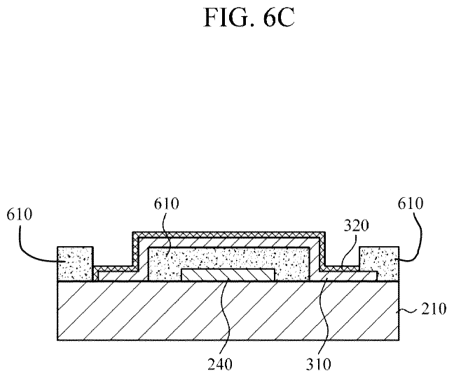

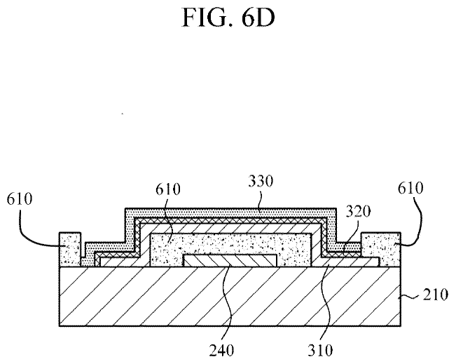

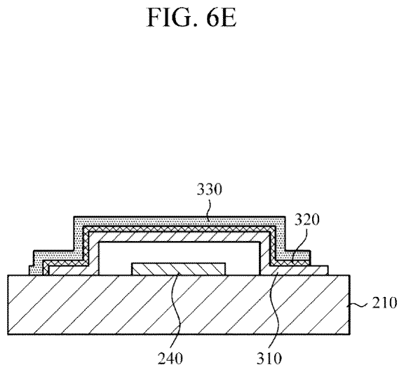

FIGS. 6A to 6E illustrate steps of manufacturing a frequency-fixed superconducting coupler, according to one or more embodiments. FIGS. 6A to 6E are cross-sectional views along a cross-section line mentioned above.

As shown in FIG. 6A, a photoresistor 610 may be first deposited on the substrate 210. Then, as shown in FIG. 6B, a first layer 310 made of a superconducting material is deposited. As shown in FIG. 6C, which may be followed by depositing a second layer 320 made of an insulator. After this step, as shown in FIG. 6D, a third layer 330 made of a superconducting material is deposited. Thereafter, as shown in FIG. 6E, the photoresistor 610 may be removed by an etching process to form an air bridge. The air bridge may be spaced apart from the substrate 210 by a distance between 5 μm and 50 μm, for example.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A superconducting computing apparatus comprising:
a substrate;
superconducting qubits formed on the substrate; and
a superconducting coupler comprised of a superconducting line and two contact pads disposed at the respective ends of the superconducting line, the contact pads having respective electrical connections with the respective superconducting qubits,
wherein the superconducting line is formed as a bridge over the substrate.

2. The superconducting computing apparatus of claim 1, wherein the superconducting coupler is an LC resonance circuit-type coupler.

3. The superconducting computing apparatus of claim 2, wherein the superconducting coupler is a frequency-fixed coupler having a resonant frequency between 1 GHz and 10 GHz.

4. The superconducting computing apparatus of claim 1, wherein the superconducting line and the two contact pads all have three layers including, in order from bottom to top, a superconducting material layer, an insulator layer, and a superconducting material layer.

5. The superconducting computing apparatus of claim 4, wherein the superconducting material comprises Aluminum (AI), Niobium (Nb), Indium (In), Alpha-Tantalum (α-Ta), Titanium (Ti), Lead (Pb), Vanadium (V), or a compound thereof.

6. The superconducting computing apparatus of claim 4, wherein the insulator has a thickness between 10 nm and 50 nm.

7. The superconducting computing apparatus of claim 6, wherein the insulator comprises aluminum oxide.

8. The superconducting computing apparatus of claim 4, wherein a superconducting material layer at a bottom of a first contact pad is connected to a capacitor of the superconducting qubit, and a superconducting material layer at a top of a second contact pad is electrically connected to a capacitor of the superconducting qubit.

9. The superconducting computing apparatus of claim 1, wherein the superconducting line and the second contact pad have a single layer of a superconducting material, and the first contact pad has three layers including, in order from bottom to top, a superconducting material layer, an insulator layer, and a superconducting material layer.

10. The superconducting computing apparatus of claim 1, wherein the bridge is vertically spaced apart from the substrate by a distance between 5 μm and 50 μm and a space between the bottom of the bridge and the top of the substrate is not occupied by solid material.

11. The superconducting computing apparatus of claim 1, further comprising a parasitic capacitor.

12. The superconducting computing apparatus of claim 1, wherein the superconducting line has a length between 100 μm and 1 mm.

13. The superconducting computing apparatus of claim 12, wherein the contact pads each have a length shorter than the length of the superconducting line.

14. The superconducting computing apparatus of claim 13, wherein the contact pads each have an area of 0.05 mm2 or less.

15. The superconducting computing apparatus of claim 1, wherein the superconducting line is formed in a crenelated shape as viewed from above.

16. The superconducting computing apparatus of claim 15, wherein the superconducting line has a total length between 100 μm and 1 mm.

17. A frequency-fixed superconducting coupler comprising:
a bridge over a substrate, the bridge comprised of superconducting material, the bridge having two ends that each comprise a respective contact pad, each contact pad having an electrical connection to a respectively corresponding superconducting qubit, and each contact pad directly or indirectly contacting the substrate, wherein there is a gap between the substrate and a corresponding portion of the bridge that is between the contact pads.

18. The frequency-fixed superconducting coupler of claim 17, wherein the gap has a distance, vertically, from the portion of the bridge to the substrate, of 5 μm to 50 μm.

19. A method of manufacturing a frequency-fixed superconducting coupler, the method comprising:
depositing a photoresist on a substrate;
then depositing a first layer made of a superconducting material;
then depositing a second layer made of an insulator;
then depositing a third layer made of a superconducting material; and
then removing the photoresist by an etching process to form a bridge over the substrate.

20. The method of claim 19, wherein the bridge is 5 μm to 50 μm above the substrate.
